(19) United States
(12) Patent Application Publication
(10) Pub. No.: US 2002/0030544 A1
(43) Pub. Date: Mar. 14, 2002

(54) System and method providing level shifting in single ended to differential conversion

(76) Inventors: Suhas R. Kulhalli, Karnataka (IN); Subhashish Mukherjee, Bangalore (IN)

Correspondence Address: TEXAS INSTRUMENTS INCORPORATED, P O BOX 655474, M/S 3999, DALLAS, TX, 75265

(21) Appl. No.: 09/940,953

(22) Filed: Aug. 28, 2001

Related U.S. Application Data
(60) Provisional application No. 60/230,232, filed on Sep. 1, 2000.

(51) Int. Cl. H03F 3/45

(52) U.S. Cl. 330/301

(57) ABSTRACT

A system is provided for enabling single ended to differential conversion of signal. The system includes N serially coupled amplifier stages, wherein N is an integer, for receiving a single ended input signal, wherein each of the N amplifier stages shifts an input signal from the previous stage to a reference associated with each of the N amplifier stages to provide a non-distorted differential output signal at the output of the Nth amplifier stage.

### TECHNICAL FIELD

The present invention relates generally to electronic systems, and more particularly to a system and method for providing level shifting of a single ended signal to an amplified differential signal wherein level shifting is achieved via (N) gain stages of a gain channel, thereby increasing amplifier performance and reducing circuitry associated with conventional systems.

### BACKGROUND OF THE INVENTION

Many advancements have been achieved in high technology circuit designs and related systems. Some of these designs are associated with electronic circuits such as amplifiers, D/A converters, A/D converters and other signal processing systems. One such area of circuit design relates to amplifier systems, wherein signals are amplified from one voltage and/or current range to another range. Often, signal ended signals, which may be referenced to a particular voltage level such as ground, are provided to an amplifier input, yet, a differential output voltage or current is desired. Level shifting circuits are often provided in order to convert a single ended input signal to a differential output signal. Unfortunately, level shifting circuits add additional cost to the overall amplifier design. Additionally, depending on the stage wherein level shifting takes place in an amplifier circuit, performance tradeoffs relating to signal quality are often made.

Generally, two well known approaches have been applied to the level-shifting problem described above. A first approach is illustrated in prior art FIG. 1. A single ended input signal 10 represents a small input signal that is provided as an input to an amplifier (not shown). The desired output range for the signal is shown at reference numeral 20, wherein the signal is shifted ½ way between a positive Vref 24a and a negative Vref 24b. In this manner, the input signal 10 may achieve maximum output range between Vref 24a and 24b without incurring distortion, that is, without exceeding the output range. In order to provide the maximum output voltage, the signal 10 may be amplified in stages shown as ever increasing amplified signals 26a, 26b, 26c, and 26d. When the signal has reached the positive Vref 24a, a level shifting occurs by subtracting, Vref 24a which is divided by two, from the signal 26d to produce a differential signal 26e. A gain multiply by two operation is then performed on signal 26e to produce the desired signal output 20. This prior art approach suffers since additional circuitry must be added to the amplifier circuitry in order to perform the described subtract and subsequent multiply operations. Additionally, optimal noise performance may not be achieved since the level shifting operation is delayed to the latter amplifier stages.

A second approach to single ended to differential level shifting is illustrated in prior art FIG. 2. An input signal 30 is first shifted by subtracting, the magnitude of the input signal 30 divided by two, from the input signal 30 to perform the desired level shifting. Subsequent amplification at signals 32a-32e is then performed to achieve the desired output signal 20. This prior art approach also has limitations. As described above, additional circuitry must be added to perform the described divide and subtract operations. Secondly, since the initial value of the input signal 30 is unknown, additional circuitry such as a D/A converter must be added in order to determine this value before the described divide and subtract operations may be performed.

In view of the above problems associated with conventional level shifting systems, there is a need for a system and/or methodology to provide a lower cost and higher performance amplifier system wherein single ended signals may be converted and amplified to full-range differential output signals without exceeding the output range.

### SUMMARY OF THE INVENTION

The present invention provides a system and methodology which facilitates a single ended signal being amplified to a differential signal across N (N being an integer) stages of a gain channel without including additional circuitry to perform level shifting. In this manner costs are reduced from conventional amplifier systems and amplifier noise performance is optimized.

In accordance with the present invention, an input signal having an unknown value or magnitude is shifted and amplified in a first amplifier stage without inclusion of additional level shifting stages. In contrast to conventional systems wherein additional stages are included at the beginning or end of an amplification stage and/or stages, the present invention enables range shifting of the single ended signal during normal amplification of the single ended signal—thus additional stages are not required. The shift is referenced to a negative or positive amplifier reference voltage defining the maximum output range for the signal. If the signal is positive, the present invention subtracts the negative reference of the amplifier from the signal during a first amplification stage of a gain channel having N stages. If the input is negative, the signal is added to the positive reference of the amplifier during the first amplification stage. Subsequent gain stages having N number of stages then provide amplification and subtraction (addition if input signal is negative) along the channel of stages until the signal reaches the desired full-scale differential output level.

The subsequent gain stages provide level shifting at values of (G−1) times the value of the reference, wherein G is the gain of a stage and the reference is equal to the value of the negative or positive references or rails of the amplifier. In this manner, partial signal adjustments are performed automatically during the amplification process without inclusion of beginning or ending exclusive level shifting stages. Noise performance is optimized since level shifting is achieved without exceeding the maximum range during each amplifier stage wherein the input signal is referenced to the amplifier positive or negative rails. The subsequent (G−1) gain stages facilitate ever increasing gains without exceeding the negative or positive rails since the value of the reference voltages are included in the gain of the stage. As will be described in more detail below, circuit implementations of the present invention enable single ended to differential conversion of an unknown input signal to a full-scale output by employing a unique configuration of amplifier stages without inclusion of additional level shifting circuitry.

The following description and the annexed drawings set forth in detail certain illustrative aspects of the invention. These aspects are indicative, however, of but a few of the various ways in which the principles of the invention may be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

FIG. 1 is a signal diagram illustrating a prior art level shifting system;

FIG. 2 is a signal diagram illustrating another prior art level shifting system;

FIG. 3a is a signal diagram illustrating a single ended to differential conversion of a signal in accordance with an aspect of the present invention;

FIG. 3b is a block diagram illustrating a subtraction along the channel system providing single ended to differential conversion in accordance with an aspect of the present invention;

FIG. 3c is a block diagram illustrating a numerical example of subtraction along the channel system providing single ended to differential conversion in accordance with an aspect of the present invention;

FIG. 4 is a schematic block diagram illustrating an exemplary circuit for single ended to differential conversion in accordance with an aspect of the present invention; and

FIG. 5 is a flow chart diagram illustrating a methodology for single ended to differential conversion in accordance with an aspect of the present invention.

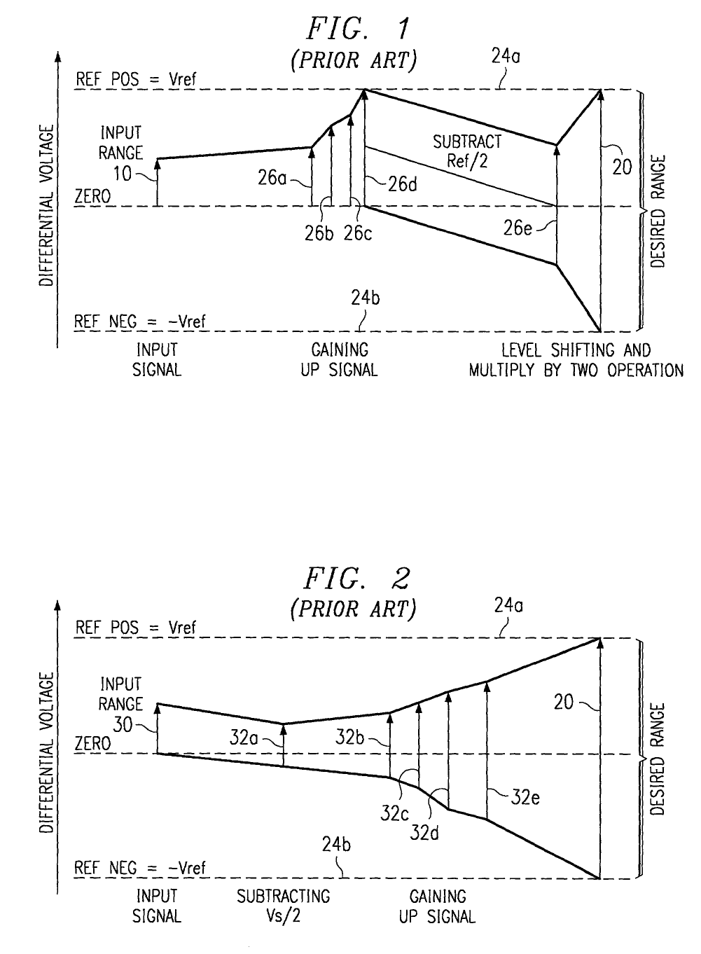

### DETAILED DESCRIPTION OF THE INVENTION

The present invention is now described with reference to the drawings, wherein like reference numerals are used to refer to like elements throughout.

The present invention relates to a system and methodology for conversion of a single ended signal to a differential signal. A single ended signal is converted by N stages of a gain channel, wherein N is an integer. At the output from each stage, the signal may be partially gained and shifted to a reference associated with the gain channel—without additional circuits dedicated solely to perform level shifting. The signal may be increasingly amplified and shifted in relation to the reference until a nondistorted differential signal is provided at the output of the N stages. Unlike conventional conversion/amplification systems which require level shifting circuits in addition to amplification circuits, the present invention employs a unique configuration and methodology to perform single ended to differential conversion wherein partial shifting and amplification of signals occur automatically along the channel of N stages. Thus, the need to added additional level shifting circuitry is mitigated.

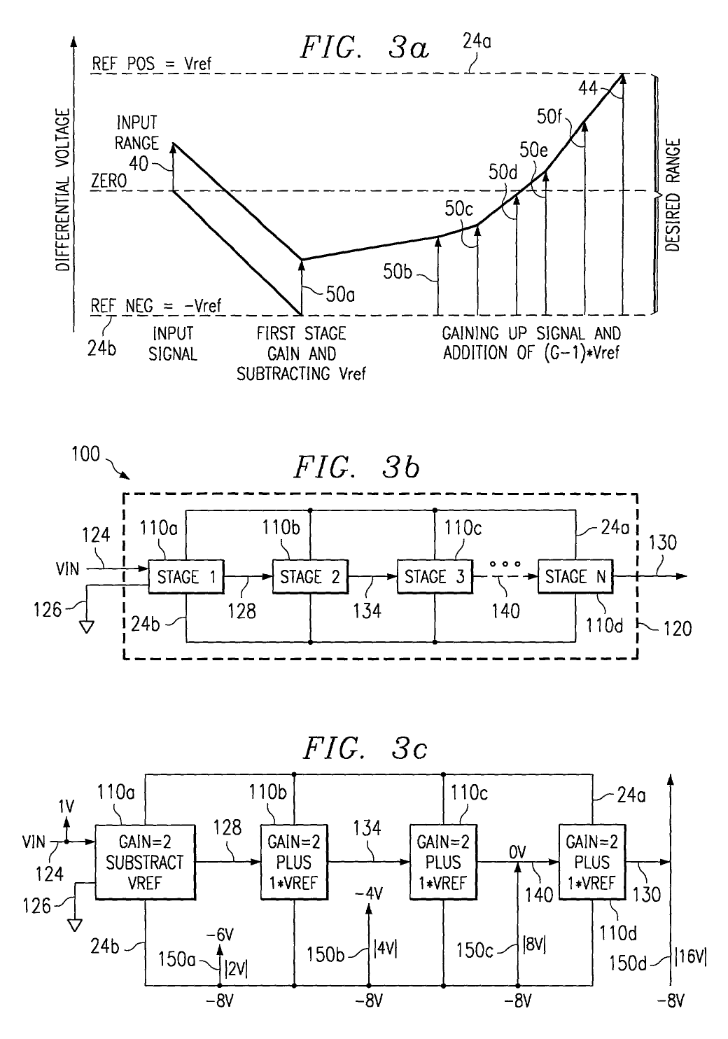

Referring initially to FIG. 3a, an exemplary signal diagram illustrates an aspect of the present invention relating to single ended to differential conversion of a signal. A single ended signal having a range 40 is provided to a first of N stages of an amplifier (See e.g., reference numerals 110a-110d in FIG. 3b below) wherein a non-distorted differential output signal having a range 44 is desired. A plurality of exemplary signal outputs 50a-50f illustrate partial shifting and amplification along N stages of a gain channel in accordance with the present invention. The input signal associated with the range 40 is shifted and amplified at the output of a first stage at reference numeral 50a. Since the input signal is positive, the shift is to a negative reference 24b of the amplifier stages. This enables the signal 40 to be amplified during the shift without distorting (e.g., cut-off, saturation) into a positive reference 24a of the stages. Shifting may be achieved, for example, by subtracting the value of the reference 24a or 24b from the input signal associated with the range 40. For example, if the reference value were 10 volts, 10 volts would be subtracted at the output of the first stage. As will be described in more detail below, if the input signal 40 is negative, the shift is to the positive reference 24a of the stages. It is to be appreciated that amplification and/or stages as described herein may refer to substantially any signal processing system wherein a signal is provided as an input to a stage and delivered as an output from the stage. For example, amplification may refer to a gain factor wherein the gain of a stage is generally greater than zero.

As the input signal associated with the range 40 is shifted, amplification may occur along the N stage outputs illustrated at reference numerals 50a-50f. It is to be appreciated that more or less stages may be provided than depicted by signal outputs associated with the ranges 50a-50f. At each stage, an adjustment and/or partial shift of the signal is made to the negative reference 24b. As will be described in more detail 10 below, the adjustment or range shift at each subsequent stage after the first stage is by a factor of G−1 (a gain(G) of the present stage minus 1) multiplied by the appropriate 24a or 24b. For example, the signal associated with the range 50b at the output of a second stage is illustrated at a larger magnitude than the signal output 50a, yet, the signal 50b is still referenced to the negative reference 24b. Signal ranges 50c-50f may also be larger in magnitude than the preceding stage. After N stages of amplification and shifting to the reference 24b, the desired differential output signal associated with the range 44 is provided.

By referencing the input signal and subsequent signals in N sequentially coupled stages to the reference 24b, significant advantages are achieved over conventional systems. As will be described in more detail below, the present invention achieves single ended to differential conversion along the N stages of a gain channel by a unique configuration of the stages wherein the reference 24a and/or 24b is added/subtracted to/from shifting portions of the stage. Also, the gain of the stage may be included with the reference in order to facilitate full-scale output swings without distortion, that is, without exceeding the range. This enables conversion of signals without adding additional stages and circuitry to exclusively perform level shifting. Additionally, by shifting partially along the channel, a signal-to-noise ratio for the system is optimized. It is noted that if the input signal 40 were negative, the signals 50a-50f would be referenced to the positive reference 24a until the desired output 44 was achieved.

Turning now to FIG. 3b, a system 100 illustrates a plurality of N serially coupled stages 110a-110d for providing single ended to differential conversion along a gain channel 120 in accordance with an aspect of the present invention. A single ended input signal having a range 124 with associated signal reference 126 is provided as an input to the first stage 110a, wherein shifting and amplification occurs to provide a first output signal having a range 128. The references 24a and 24b depict the power rails for the channel 120. The output of the first stage 110a wherein the relationship between the input signal 124 and the first output signal 128 associated therewith is provided may be described by the following equation:

Equation 1: Output (Stage 110a)=Gain (Stage 110a)*the Input 124+reference 24b,

wherein the gain is generally greater than zero and the input signal is positive. Therefore the first stage 110a performs the function of amplifying the input signal by the gain of the stage 110a and then shifting the amplified signal by the reference value 24b, wherein the shifting or subtraction is independent of the gain.

If the input signal is negative, the following equation describes the output of stage 110a:

Equation 2: Output (Stage 110a)=Gain (Stage 110a)*the Input 124+reference 24a

Referring briefly back to FIG. 3a, Equation 1 describes the signal output 50a wherein the reference 24b is subtracted when the input signal is positive. Referring again to FIG. 3b, the next stage 110b provides a gain and shift of the first output signal wherein the reference 24a or 24b is included to enable level shifting within the stage. Similarly, subsequent stages 110c and 110d also include a reference 24a or 24b within the stage functionality. In this manner, a non-distorted differential signal is provided at an output 130 of the channel 120 without adding additional circuitry to exclusively perform level shifting. Although the system 100 depicts four stages 110a-110d, it is to be appreciated that more or less than four stages may be utilized by the present invention. Each of the N stages 110b-110c provides an input to output relationship based on the following equation:

Equation 3: Output (Stage (N), e.g., 110b, 110c, 110d)=Gain (Stage N)*the Output (Stage N−1)+(the reference 24a*(Gain (Stage (N))−1),

wherein the Output of Stage (N−1) refers to the output of the preceding stage. For example, the signal associated with the range 128 is the Output of Stage (1) and is provided as an input to Stage (2) 110b. Stage (2) 110b provides an output 134 and Stage (3) 110cprovides an output 140, respectively. The amount of range shifting for a given stage is a function of the appropriate reference 24a or 24b and the gain of that stage. More particularly, the amount of range shifting is a product of the appropriate reference and (G−1), wherein G represents the gain of that particular stage. If the input signal associated with the 124 is negative, the output for Stages 110b-110c is described by the following equation:

Equation 4: Output (Stage (N), e.g., 110b, 110c, 110d) Gain (Stage N)*the Output (Stage N−1)−(the reference 24a*(Gain (Stage (N))−1).

The above equations describe a system for partially shifting and gaining a signal to provide a differential output signal 130. As described above, a non-distorted signal is provided over N stages of the channel 120. A mathematical proof follows which provides more detail in regard to this functionality.

Mathematical Proof

Suppose a single ended input signal lies within the range 0 to Vs, with the desired differential signal range being −Vref to +Vref. Hence the gain (G) of the entire system required is:

1) Vref−(−Vref)=2* Vref, thus, to achieve a full output swing, Vs*G=2*Vref.

If the total system gain (G) is achieved through n stages, of gain G₁, G₂, G₃ . . . G_{N}, respectively.

Then,

G₁*G₂*G₃* . . . *G_{N}=G (2)

Let V_{INP} be the input signal, and V₁, V₂ . . . be the outputs of stages 1, 2 . . . , respectively. Thus V_{N} is the output of stage N.

So we have, 0<V_{INP}<V_{S} and at the output of the last stage it is desired −Vref<V_{N}<Vref

Looking at the individual stage outputs,

0<V_{INP}<V_{S} . . .

0<V_{INP}*G₁<V_{S}*G₁

V₁=Vᵢₙₚ*G₁−V_{ref}

−Vref<V₁<V_{S}*G₁−Vref . . . output of stage 1

Now recall that stages 2, 3 . . . n are dictated by Equation 3, therefore

V₂=G₂*V₁+V_{ref}*(G₂−1). Thus

−Vref*G₂+Vref*(G₂−1)<V₂<(Vs*G₁−Vref)*G₂+Vref*(G₂−1)

=−Vref<V₂<Vs*G₁*G₂−Vref . . . output of stage 2

−Vref*G3+Vref*(G₃−1)<V₃<(Vs*G₁*G₂−Vref)*G₃+Vref*(G₃−1)

=−Vref<V₃<Vs*G₁ *G₂ *G₃−Vref . . . output of stage 3

=−Vref<V_{N}<Vs*G₁ *G₂ *G₃ *G₄ . . . *G_{N}−Vref . . . output of stage N

=−Vref<V_{N}<Vs*G−Vref . . . from (2)

But VS*G=2*Vref . . . from (1)

=−Vref<V_{N}<2*Vref−Vref

=−Vref<V_{N}<Vref

which is the desired relationship.

Thus, by shifting the signal partially at each stage, a single ended input signal having a range of 0−Vs is mapped to the desired range. At no point does the signal exceed the limits −Vref and Vref, thus not exceeding the range limits of the stages. This process may be employed effectively for switched capacitor as well as continuous time implementations.

Turning now to FIG. 3c, a numerical example of single ended to differential conversion of a signal as depicted in FIG. 3b is illustrated in accordance with an aspect of the present invention. It is to be appreciated that the following example is for illustrative purposes only. A plurality of numerical values may be associated with any of the N stages described in accordance with the present invention. For example, a plurality of gain values, reference voltage values, and the number of stages may be employed.

As illustrated in FIG. 3c, an exemplary input signal 124 has an exemplary range of 1 v. The references 24a and 24b for this example are assigned the values of +8 v and −8 v, respectively. Stages 110a through 110d are assigned gain values of 2. Therefore, with an input range of 1 v the desired full-scale differential output range is ±8 v or 16 v peak to peak. Thus, the combined gain of each stage, which is 2 * 2 * 2 * 2=16 provides the desired amount of overall gain to boost the input signal range 124 to 16 v. It is to be appreciated that the gain stages 110a-110d are not required to be of the same gain value. For example, the gain for stage 110a may be 1, the gain for stage 110b may be 2, the gain for stage 110c may be 0.5, and the gain for stage 110d may be 16, wherein 1 * 2 * 0.5 * 16=16.

Assuming a gain for stage 110a of 2, and a positive input range of 1 v, the output signal 128 is depicted at reference numeral 150a having a signal magnitude range of 2 and shifted minus 8 v. This value is derived from gaining the input signal range of 1 v by 2 which is 2 v and subtracting the value of the reference 24b which is -8 v, thus 1 * 2−8 v=−6 v. The output 134 from stage 110b is depicted at reference numeral 150b having a signal magnitude range of 4 v and shifted −8 v. This value is derived from gaining the output range from stage 110a which was 2 v by 2 and adding the gain of stage 110b1 * the reference 24b. Thus, 2 * 2+(2−1, which is the gain of stage 110b−1) * −8 v=−4 v. Thus, stage 110b gains signal 128 by 2 and shifts the amplified signal range down to the rail 24b. The gains of stages 110cand 110d may be similarly derived as stage 110b wherein the output of stage 110cis referenced to the rail 24b having a magnitude of 8 v and 16 v respectively, yet are referenced to the rail 24b.

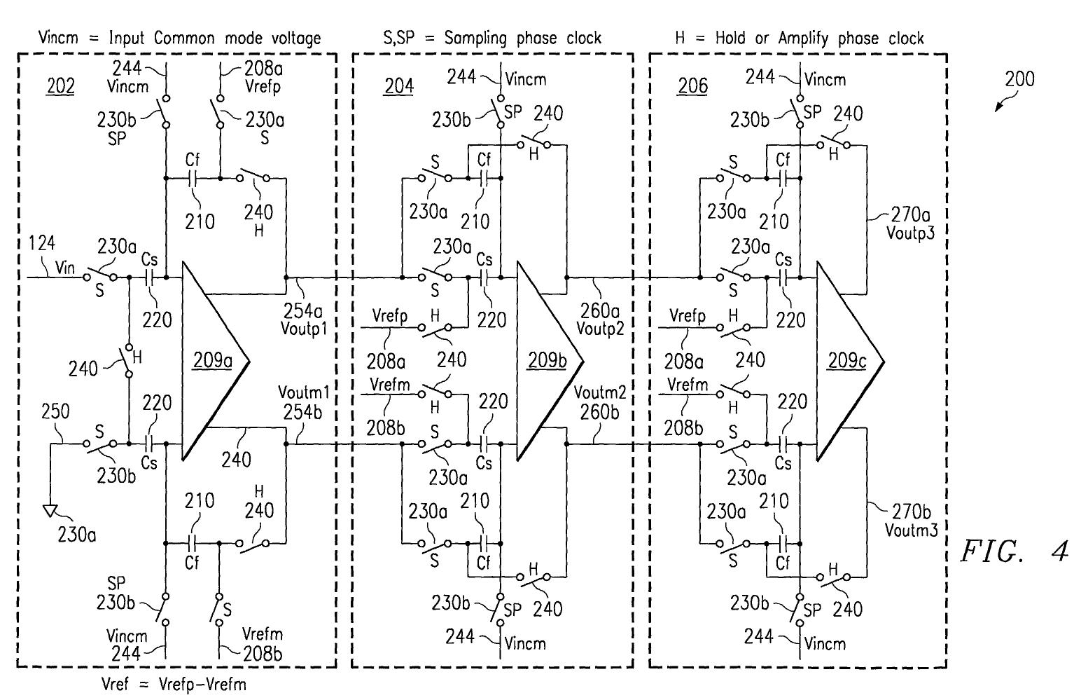

Referring now to FIG. 4, an exemplary three-stage amplifier system or gain channel 200 illustrates an aspect of the present invention relating to a single ended to differential conversion of a signal. The system 200 represents a unique configuration of amplifier stages 202, 204, and 206, wherein signals are partially shifted and amplified during the amplification process by including reference voltages Vrefp 208a and Vrefm 208b associated with the stages within portions of the amplification process. This may be achieved, for example, by replacing common mode connections as associated with conventional systems with connections to the reference voltages 208a and 208b associated with the stages. In this manner, level shifting may occur without the addition of exclusively dedicated level shifting circuits or components. As described above, N additional stages may also be included, if desired.

The system 200 depicts a phase-sampled circuit wherein amplifiers 209a, 209b, and 209c are configured via capacitors Cf (feedback caps) 210, and input sampling capacitors Cs 220. The capacitors Cf 210 and Cs 220 are selected for a desired impedance via sampling phase clocks denoted as S 230a and SP 230b, respectively. It is to be appreciated that other linear configurations may be utilized by the present invention. These may include circuits wherein resistive elements are employed for feedback and input amplifier components in place of capacitors, for example. By adjusting the frequency of the phase clocks 230a and 230b, gains for the stages 202, 204, and 206 may be adjusted to a desired value wherein a desired ratio may be selected for the capacitors Cf 210 and Cs 220. After signals, which are described below, have been sampled onto the capacitors Cs 210 and Cf 204, a Hold phase clock 240 is employed to amplify and provide the desired outputs from the stages 202, 204, and 206. A common mode input (Vincm) 244 is also provided in order that common mode signals may be rejected by the system 200 as is well understood.

The first stage 202 provides a gain and a shift to the input signal 124 which is referenced to an associated ground 250. Outputs of the stage 202 are depicted at reference numerals 254a and 254b and illustrated as Voutp1 and Voutm1, respectively. The differential output for stage 202 is described by the following equations:

Equation 5: Output (Stage 202)=Voutp1−Voutm1,

wherein equation 5 is also equal to:

Equation 6: Output (Stage 202)=Cs/Cf*Vin (e.g., input signal 124)−Vref,

wherein Vref=Vrefp 208a−Vrefm 208b, and wherein equation 6 is also equal to:

Equation 7: Output (Stage 202)=Gain (Stage 202)*Vin−Vref.

In contrast to conventional systems wherein common mode voltages 244 would be connected in place of the references Vrefp 208a and Vrefm 208b, the present invention shifts the input signal 124 automatically in the first stage 202 by sampling the references 208a and 208b instead of the common mode voltages 244. Thus, additional circuitry to provide level shifting is unnecessary.

The outputs for the subsequent stages 204 and 206 may be configured differently than stage 202 in order to provide gain and subsequent shifting without exceeding the references 208a and 208b. For example, the output for stage 204 illustrated as Voutp2 260a and Voutm2 260b may be described by the following equations:

Equation 8: Output (Stage 204) Voutp2−Voutm2,

wherein equation 8 is also equal to:

Equation 9: Output (Stage 204)=(1+Cs/Cf)*Vout1+Cs/Cf * Vref,

wherein Vref=Vrefp 208a−Vrefm 208b, and wherein equation 9 is also equal to:

Equation 10: Output (Stage 204)=Gain (Stage 204)*Vout1+(Gain (Stage 204)−1)*Vref.

Therefore amplifier stage 204 has an amplification component and a level shift component, wherein the level shift is a function of Vref.

The output for stage 206 illustrated as Voutp3 270a and Voutm3 270b may be similarly described by the following equations:

Equation 11: Output (Stage 206)=Voutp3−Voutm3,

wherein equation 10 is also equal to:

Equation 12: Output (Stage 206)=(1+Cs/Cf)*Vout2+Cs/Cf*Vref,

wherein Vref=Vrefp 208a−Vrefm 208b, wherein equation 12 is also equal to:

Equation 13: Output (Stage 206)=Gain (Stage 206)*Vout2+(Gain (Stage 206)−1)* Vref.

It is noted that the references Vrefp 208a and Vrefm 208b are included as inputs to the subsequent stages 204 and 206. As opposed to conventional systems wherein common mode inputs 244 may be tied to the nodes at 208a and 208b, the present invention automatically enables partial shifting and amplification throughout the amplifier stages 204 and 206 by utilizing the references 208a and 208b in place of the common mode voltages 244. Thus, level shifting and amplification is achieved according to this exemplary aspect of the present invention without exceeding the maximum output range and without inclusion of additional components by employing the unique configuration, wherein reference voltages are utilized in place of the common mode voltages 244.

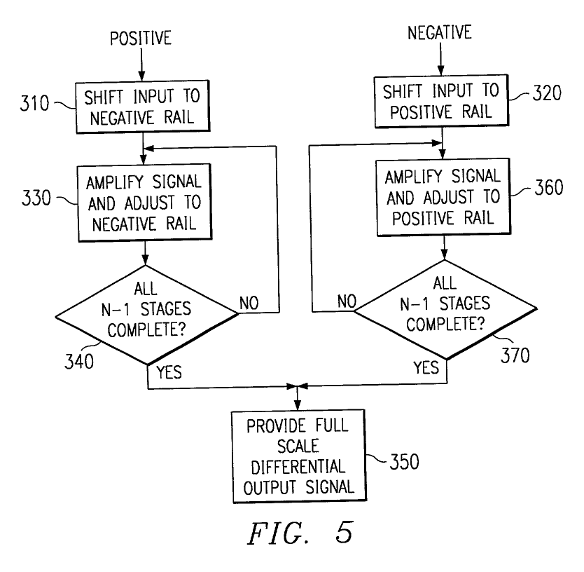

Referring to FIG. 5, a flow chart diagram illustrates a methodology for providing single ended to differential conversion of a signal in accordance with an aspect of the present invention. If the input is positive, the input signal is shifted to the negative rail at step 310. This may be achieved by subtracting the reference as described above from the input signal. The signal may also be amplified at step 310. At step 330, the shifted signal from step 310 is amplified and adjusted to the negative rail. This may be achieved by providing a gain to the signal and subtracting a factor of the gain minus one multiplied by the reference. At step 340, a determination is made as to whether all N−1 additional stages have been completed. If all N−1 additional stages have not been completed at step 340, the process proceeds back to step 330 to continue amplifying and adjusting the signal. If all N−1 additional stages have been completed at step 340, the process proceeds to step 350 wherein the full-scale differential output signal is provided as a converted single ended signal.

If the input is negative, the input signal is shifted to the positive rail at step 320. This may be achieved by adding the reference as described above to the input signal. The signal may also be amplified at step 320. At step 360, the shifted signal from step 320 is amplified and adjusted to the positive rail. This may be achieved by providing a gain to the signal and adding a factor of the gain minus one multiplied by the reference. At step 370, a determination is made as to whether all N−1 additional stages have been completed. If all N−1 additional stages have not been completed at step 370, the process proceeds back to step 360 to continue amplifying and adjusting the signal. If all N−1 additional stages have been completed at step 370, the process proceeds to step 350 wherein the full-scale differential output signal is provided as a converted single ended signal.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Furthermore, to the extent that the term “includes” is used in either the detailed description or the claims, such term is intended to be inclusive in a manner similar to the term “comprising.”

What is claimed is:

1. A system providing single ended to differential conversion of a signal, comprising:
N serially coupled amplifier stages, wherein n is an integer, for receiving a single ended input signal, wherein each of the n amplifier stages shifts an input signal from the previous stage to a reference associated with each of the N amplifier stages to provide a non-distorted differential output signal at the output of the Nth amplifier stage:

2. The system of claim 1, further comprising a positive and a negative reference.

3. The system of claim 1, wherein the single ended input signal is positive.

4. The system of claim 3, wherein a first stage of the N serially coupled stages provides an output based upon a product of a gain of the first stage and an input of the first stage and a reference of the first stage subtracted therefrom.

5. The system of claim 4, wherein the gain is greater than zero for the first stage.

6. The system of claim 3, wherein each of the subsequent stages of the N serially coupled stages after the first stage provide an output based upon a gain of the respective stage multiplied by an output of a previous stage plus the reference multiplied by the gain of the respective stage minus 1.

7. The system of claim 6, wherein the gain of the subsequent N serially coupled stages is greater than zero.

8. The system of claim 1, wherein the single ended input signal is negative.

9. The system of claim 8, wherein a first stage of the N serially coupled stages provides an output based upon a product of a gain of the first stage and an input of the first stage and a reference of the first stage added thereto.

10. The system of claim 9, wherein the gain is greater than zero for the first stage.

11. The system of claim 8, wherein the subsequent stages of the N serially coupled stages after the first stage provide an output based upon a gain of the respective stage multiplied by an output of a previous stage minus the reference multiplied by the gain of the respective stage minus 1.

12. The system of claim 11, wherein the gain of the subsequent N serially coupled stages is greater than zero.

13. The system of claim 1, wherein capacitors are employed as a ratio to adjust the gain of the N amplifier stages.

14. The system of claim 1, wherein resistors are employed as a ratio to adjust the gain of the N amplifier stages.

15. A method for providing single ended to differential conversion of a signal, comprising the steps of:
shifting a single ended input signal to at least one of a negative and positive reference to provide an output signal; and
amplifying the output signal while providing adjustments to the output signal corresponding to the negative and positive reference to provide a non-distorted differential output signal.

16. The method of claim 15, further comprising the steps of: determining whether the input is positive or negative.

17. The method of claim 16, wherein if the input is positive, the shifting of the single ended input signal is performed by forming a product of a gain of a first stage and an input of the first stage and a reference of the first stage subtracted therefrom.

18. The method of claim 16, wherein if the input is negative, the shifting of the single ended input signal is performed by forming a product of a gain of a first stage and an input of the first stage and a reference of the first stage added thereto.

19. The method of claim 16, wherein if the input is positive, the adjustments are based upon a gain of a respective stage multiplied by an output of a previous stage plus the reference multiplied by the gain of the respective stage minus 1.

20. The method of claim 16, wherein if the input is negative, the adjustments are based upon a gain of a respective stage multiplied by an output of a previous stage minus the reference multiplied by the gain of the respective stage minus 1.

21. A system providing single ended to differential conversion of a signal, comprising:
means for shifting a single ended input signal to at least one of a negative and positive reference to provide an output signal; and
means for providing adjustments to the output signal corresponding to the negative and positive reference to provide a non-distorted differential output signal.

22. The system of claim 21, further comprising:
means for determining whether the input is positive or negative.

23. The system of claim 22, wherein if the input is positive, the shifting of the single ended input signal is performed by forming a product of a gain of a first stage and an input of the first stage and a reference of the first stage subtracted therefrom.

24. The system of claim 22, wherein if the input is negative, the shifting of the single ended input signal is performed by forming a product of a gain of a first stage and an input of the first stage and a reference of the first stage added thereto.

25. The system of claim 22, wherein if the input is positive, the adjustments are based upon a gain of a respective stage multiplied by an output of a previous stage plus the reference multiplied by the gain of the respective stage minus 1.

26. The system of claim 22, wherein if the input is negative, the adjustments are based upon a gain of a respective stage multiplied by an output of a previous stage minus the reference multiplied by the gain of the respective stage minus 1.

27. A system providing single ended to differential conversion of a signal, comprising:
a first amplifier stage for receiving a single ended input signal, wherein the first amplifier stage shifts the input signal to a reference associated with the first amplifier stage to provide a shifted output signal; and
N serially coupled amplifier stages, wherein N is an integer, operatively coupled to the first amplifier stage, wherein each of the N amplifier stages amplifies the amplified shifted output signal from a previous stage and shifts the amplified shifted output signal to a reference associated with each of the N amplifier stages, wherein an amount of shifting is a function of the reference associated with each of the N amplifier stages and a gain of the stage performing the shifting to thereby provide a non-distorted differential output signal at the output of the Nth stage.

28. The system of claim 27, further comprising a positive and a negative reference.

29. The system of claim 28, wherein the single ended input signal is positive.

30. The system of claim 29, wherein the first amplifier stage provides an output based upon a product of the gain of the first amplifier stage and an input of the first amplifier stage and the reference of the first stage subtracted therefrom.

31. The system of claim 29, wherein the N serially coupled amplifier stages after the first stage provide an output based upon a product of the gain of the respective stage and the output of a previous stage which is shifted by an amount based on a product of the reference and a (G−1), wherein G represents the gain of the respective stage.

32. The system of claim 28, wherein the single ended input signal is negative.

33. The system of claim 32, wherein the first amplifier stage provides an output based upon a product of the gain of the first amplifier stage and an input of the first amplifier stage and the reference of the first stage added thereto.

34. The system of claim 32, wherein the N serially coupled amplifier stages after the first stage provide an output based upon a product of the gain of the respective stage and the output of a previous stage which is shifted by an amount based on a product of the reference and a (G−1), wherein G represents the gain of the respective stage.
